(19) United States
(12) Patent Application Publication
(10) Pub. No.: US 2011/0051484 A1
(43) Pub. Date: Mar. 3, 2011

(54) LOW ACTIVE POWER CONTENT ADDRESSABLE MEMORY

(75) Inventors: Albert M. Chu, Essex Junction, VT (US); Daryl M. Seitzer, Essex Junction, VT (US); Abhijeet R. Tanpure, Essex Junction, VT (US)

(73) Assignee: INTERNATIONAL BUSINESS MACHINES CORPORATION, Armonk, NY (US)

(21) Appl. No.: 12/549,494

(22) Filed: Aug. 28, 2009

(51) Int. Cl. G11C 15/04; G11C 15/00

(52) U.S. Cl. 365/49.12; 365/49.17

(57) ABSTRACT

A dynamic, content addressable memory (CAM) cell includes a match line, a write line, a first pair of complementary bit lines for read and search operations, and a second pair of complementary bit lines for write operations; a first storage transistor connected between one of the first pair of complementary bit lines and the match line; a second storage transistor connected between the other of the first pair of complementary bit lines and the match line; a first write transistor connected between a gate of the first storage transistor and one of the second pair of complementary bit lines; and a second write transistor connected between a gate of the second storage transistor and the other of the second pair of complementary bit lines, with both the first and second write transistors having a gate connected to the write line.

### BACKGROUND

The present invention relates generally to integrated circuit (IC) memory devices and, more particularly, to a low active power content addressable memory (CAM) cell and array structure.

A content addressable memory (CAM) is a storage device in which storage locations can be identified by both their location or address through a read operation, as well as by data contents through a search operation. An access by content starts by presenting a search argument to the CAM, wherein a location that matches the argument asserts a corresponding match line. One use for such a memory is in dynamically translating logical addresses to physical addresses in a virtual memory system. In this case, the logical address is the search argument and the physical address is produced as a result of the dynamic match line selecting the physical address from a storage location in a random access memory (RAM). Accordingly, exemplary CAM search operations are used in applications such as address-lookup in network ICs, translation lookaside buffers (TLB) in processor caches, pattern recognition, data compression, etc. CAMs are also frequently used for address-look-up and translation in Internet routers and switches.

A CAM typically includes an array of CAM cells arranged in rows and columns, where each row of the CAM array corresponds to a stored word. The CAM cells in a given row couple to a word line and a match line associated with the row. The word line connects to a control circuit that can either select the row for a read/write operation or bias the word line for a search. The match line carries a signal that, during a search, indicates whether the word stored in the row matches an applied input search word. Each column of the conventional CAM array corresponds to the same bit position in all of the CAM words, while the CAM cells in a particular column are coupled to a pair of bit lines and a pair of search-lines associated with the column. Search data is applied to each pair of search lines, which have a pair of complementary binary signals or unique ternary signals thereon that represent a bit of an input value. Each CAM cell changes the voltage on the associated match line if the CAM cell stores a bit that does not match the bit represented on the attached search lines. If the voltage on a match line remains unchanged during a search, the word stored in that row of CAM cells matches the input word.

### SUMMARY

In an exemplary embodiment, a dynamic, content addressable memory (CAM) cell includes a match line, a write line, a first pair of complementary bit lines for read and search operations, and a second pair of complementary bit lines for write operations; a first storage transistor connected between one of the first pair of complementary bit lines and the match line; a second storage transistor connected between the other of the first pair of complementary bit lines and the match line; a first write transistor connected between a gate of the first storage transistor and one of the second pair of complementary bit lines; and a second write transistor connected between a gate of the second storage transistor and the other of the second pair of complementary bit lines, with both the first and second write transistors having a gate connected to the write line.

In another embodiment, a dynamic, content addressable memory (CAM) array includes a plurality of CAM cells arranged in rows and columns, with each row including a match line and a write line, and each column including a first pair of complementary bit lines for read and search operations, and a second pair of complementary bit lines for write operations, wherein each of the plurality of CAM cells further includes a first storage transistor connected between one of the first pair of complementary bit lines and the match line; a second storage transistor connected between the other of the first pair of complementary bit lines and the match line; a first write transistor connected between a gate of the first storage transistor and one of the second pair of complementary bit lines; and a second write transistor connected between a gate of the second storage transistor and the other of the second pair of complementary bit lines, with both the first and second write transistors having a gate connected to the write line.

In another embodiment, a method of operating a dynamic, content addressable memory (CAM) cell having a match line, a write line, a first pair of complementary bit lines for read and search operations, and a second pair of complementary bit lines for write operations, a first storage transistor connected between one of the first pair of complementary bit lines and the match line, a second storage transistor connected between the other of the first pair of complementary bit lines and the match line, a first write transistor connected between a gate of the first storage transistor and one of the second pair of complementary bit lines, and a second write transistor connected between a gate of the second storage transistor and the other of the second pair of complementary bit lines, with both the first and second write transistors having a gate connected to the write line, includes: performing a read operation of the cell by maintaining the write line low and initially preconditioning the match line and the first pair of complementary bit lines low, selecting the cell for the read operation by bringing the match line high, and determining which of the first and storage transistors has a charge stored on its gate by detecting a charge appearing on one of the first pair of complementary bit lines, via the match line; and performing a match operation on the cell by maintaining the write line low and initially preconditioning the match line high, driving search data onto the first pair of complementary bit lines, and determining whether the cell data matches the data presented on the first pair of complementary bit lines such that match line remains high in the event of a match and the match line discharges in the event of a mismatch.

### BRIEF DESCRIPTION OF THE SEVERAL VIEWS OF THE DRAWINGS

Referring to the exemplary drawings wherein like elements are numbered alike in the several Figures:

FIG. 1 is a schematic diagram of a dynamic five-transistor (5T) CAM cell in accordance with an embodiment of the invention;

FIG. 2 is a schematic diagram of an alternative embodiment of the 5T CAM cell of FIG. 1; and

FIG. 3 is a schematic diagram of an exemplary CAM array in which the CAM cells of FIGS. 1 and 2 may be incorporated.

### DETAILED DESCRIPTION

With respect to CAM devices, a static random access memory (SRAM) cell generally provides better performance and accessibility due to the high performance devices available and static nature of the memory (i.e., the data is maintained in a latch without the need for refresh so long as power remains supplied to the device). However, power and density requirements have led to increasing interest in a dynamic random access memory (DRAM) based CAM cell. For a ternary CAM cell capable of storing a “don't care” state, there may an exemplary transistor device reduction may be from a 16-T static CAM cell to a 6-T dynamic CAM cell. Notwithstanding, even with the smaller DRAM based CAM designs, the active power and performance data will still ultimately dictate the cell and RAM architecture.

Accordingly, disclosed herein is a dynamic CAM cell configuration that improves on the power and performance issues faced by a CAM. Whereas previous dynamic CAM cell solutions have focused on improved charge storage time design and reliability, the same has not heretofore addressed minimizing capacitive loading during read and search operations. In particular, previous gain cell designs have utilized a single set/pair of bitlines for all read/write/search operations. This leads to greater capacitive loading on the bitlines, which the cell selected for a read/search operation must discharge. In contrast, the embodiments disclosed herein separate the write data bitlines from the read/search data bitlines. This separation helps reduce the capacitive loading on read/search data bitlines during read/search operations. Lower capacitive loading on the read/search data bitlines during read/search operations in turn leads to faster read and/or search times, improved active power performance numbers, and taller bitline structures leading to denser designs.

Assuming the usage of trench capacitors as storage elements, no power lines are required within the cell. Although such a design has increases the number of bitlines from 2 to 4, the read/search bitlines may be interdigitated with the write bitlines, thus allowing isolation of complimentary bitlines during read, search, and write operations reducing capacitive coupling and improving noise immunity. Since no power lines are required, the cell can be physically designed to accommodate 4 bit/search lines without an area impact.

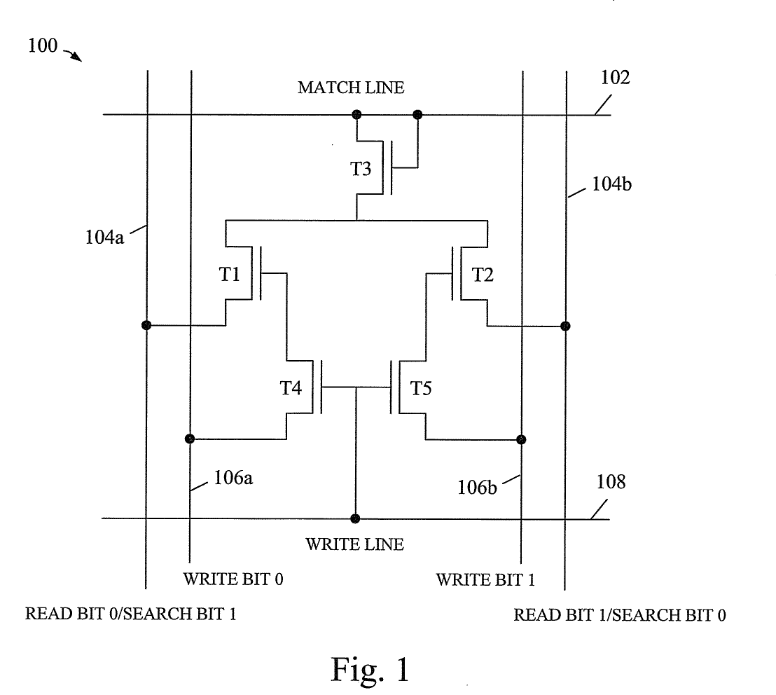

Referring now to FIG. 1, there is shown a schematic diagram of a dynamic five-transistor (5T) CAM cell 100 in accordance with an embodiment of the invention. The ternary CAM cell 100 includes a pair of storage transistors, T1 and T2 (e.g., NFET devices), connected drain-to-source between a match line 102 and a first pair of bit lines 104a, 104b, that serve as both read bit lines and search bit lines. A diode-connected transistor T3 is coupled between the match line 102 and the common drain terminal of the storage transistors T1, T2. As also shown in FIG. 1, the cell 100 further includes a pair of write transistors, T4 and T5, connected drain-to-source between the gates of storage transistors T1 and T2, respectively, and a second pair of bit lines 106a, 106b, that serve as write bit lines. The write transistors T4 and T5 are gated by a high signal on a write line 108.

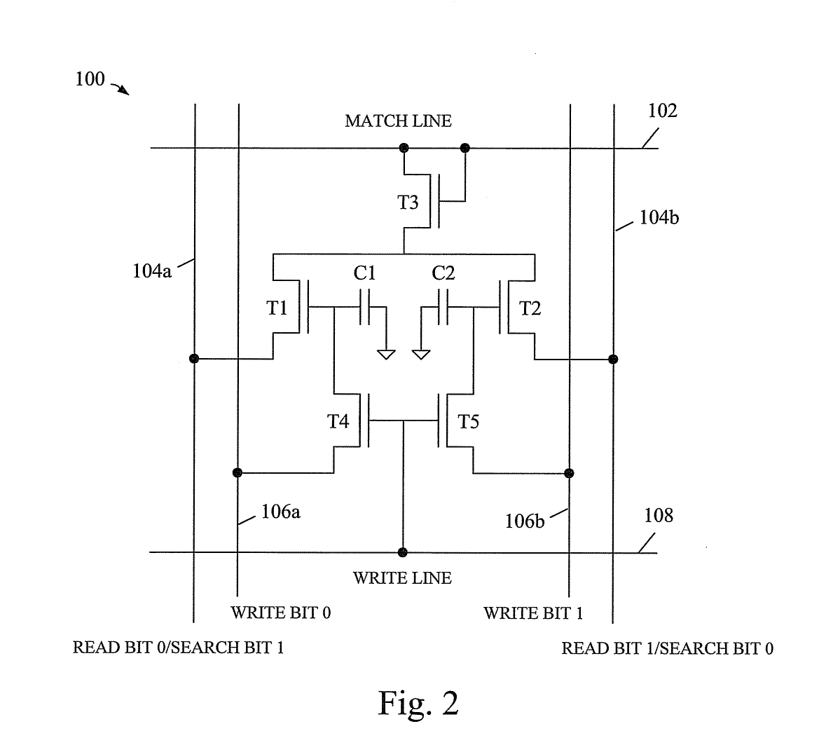

In lieu of utilizing only the gates of transistors T1 and T2 as the storage nodes of the cells, it is also contemplated that the CAM cell 100 may also be provided with deep trench storage capacitors for data storage, wherein a buried plate of the capacitors is connected to ground (GND). FIG. 2 is a schematic diagram of an alternative embodiment of the 5T CAM cell 100 of FIG. 1, additionally depicting the trench storage capacitors C1, C2, having one electrode in common with the associated storage transistor gate, and the other buried plate electrode coupled to ground.

For a write operation of the CAM cell 100, the match line 102, read/search bit line pair 104a, 104b, and write bit line pair 106a, 106b are all preconditioned to the same potential, such as GND or V_{DD}. This will prevent any static power consumption and allow the read/search bit line pair 104a, 104b to serve as shielding for the write bit line pair 106a, 106b. Data is then driven on the write bit line pair 106a, 106b, and the potential on the write line 108 is brought to logic high. Whichever of the complementary write bits (write bit 0, write bit 1) has the logic high signal thereon will cause the corresponding gate of the storage transistor T1 or T2 (and trench capacitor C1 or C2 of FIG. 2) of the respective storage node to charge, thus writing the data to the cell.

In order to perform a read operation of the cell 100, the write line 108 is held low (GND), while the match line 102 and read/search bit line pair 104a, 104b are initially preconditioned low (GND). The row corresponding to the location of the cell 100 is then selected by bringing its respective match line 102 high (V_{DD}) (while the remaining match lines in other rows remain held low. Whichever gate of the two storage transistors T1 or T2 (and trench capacitors C1 or C2) has a charge stored thereon, that transistor will conduct and couple the high signal on the match line 102, via the diode connected transistor T3 onto the corresponding one of the read/search bit line pair 104a, 104b. A sense amplifier (not shown in FIG. 1 or 2) can then detect a voltage differential on the read/search bit line pair 104a, 104b and thus read the data.

For a match operation, the write line 108 is again held low (GND), while the match line 102 is initially preconditioned high (V_{DD}). Search data is then driven onto read/search bit line pair 104a, 104b. If the cell data matches the data presented on the read/search bit line pair 104a, 104b, the match line 102 will remain high. On the other hand, if there is a mismatch, then the match line 102 will begin to discharge via transistor T3, through whichever of T1 and T2 has the gate charge thereon, and through the corresponding grounded search line read/search bit line 104a or 104b. As such, for a practical array device having a row that has all data cells matching, the corresponding match line will maintain a high (V_{DD}) state thereon.

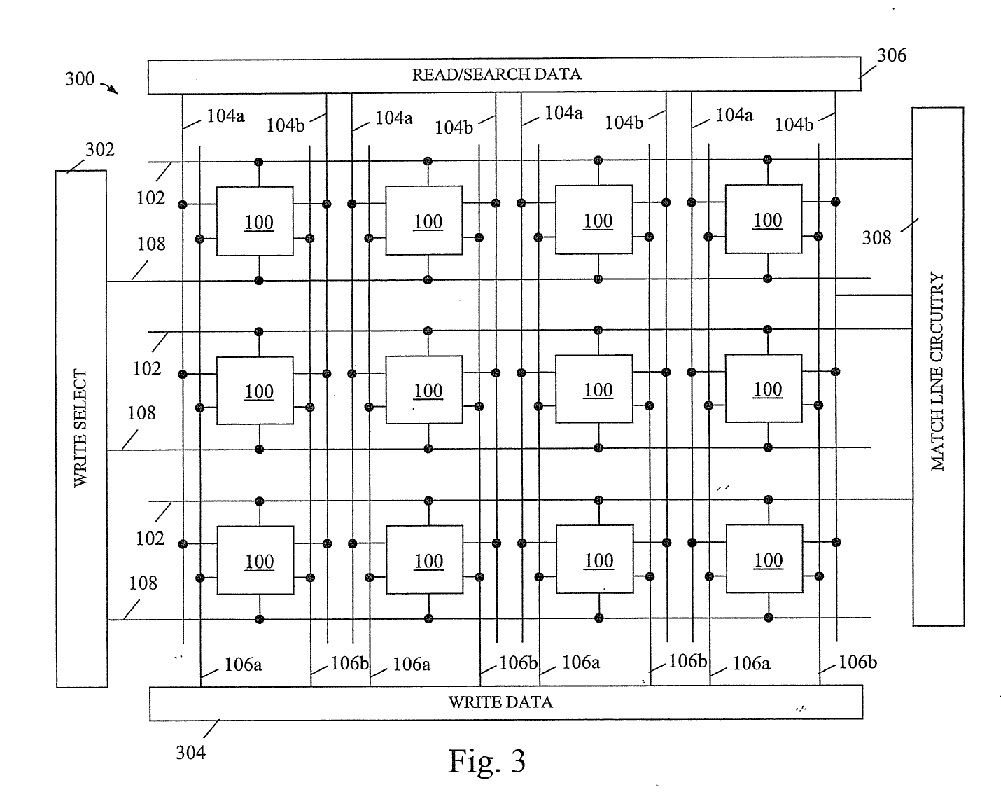

With respect to a practical array device, FIG. 3 is a schematic diagram of an exemplary CAM array 300 in which the CAM cells 100 of FIGS. 1 and 2 may be incorporated. In the example depicted, the CAM array 300 includes a plurality of individual cells 100, arranged into rows (in a word line direction) and columns (in a bit line direction). Although a simple 3×4 array is depicted for illustrative purposes, it will be appreciated that an actual CAM array may have hundreds or thousands of bits in the row and column directions.

As shown in FIG. 3, write (row) select circuitry 302 used to decode an select a specific row when writing a word of data to an array, as presented on the column-wise write bit line pairs 106a, 106b via the write data circuitry 304. In addition, the read/search data circuitry 306 is used to either read out data along a selected row or to present data to be searched to the array. In either instance, a selected match line is used for reading or searching via the match line circuitry 308. Again for the practical CAM array 300, each row includes a corresponding match line 102. The match lines 102 are preconditioned to a logical high value such that if any one or more data bits within that row that does not match the corresponding bit in the search data 104a, 104b, then the match line 102 is discharged to a logical low value, signifying a mismatch condition. Conversely, if each data bit within that row matches the corresponding bit in the search data 104a, 104b, then the match line 102 is not discharged, signifying a match condition.

As will thus be appreciated, the present CAM cell and array embodiments provide reduced capacitive loading on the read/search data bit lines during read/search operations, while maintaining a common match/read word line without the need for a ground connection. This in turn leads to faster read and/or search times, as well as improved active power performance numbers without greatly sacrificing device real estate.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof Therefore, it is intended that the invention not be limited to the particular embodiment disclosed as the best mode contemplated for carrying out this invention, but that the invention will include all embodiments falling within the scope of the appended claims.

What is claimed is:

1. A dynamic, content addressable memory (CAM) cell, comprising:
a match line, a write line, a first pair of complementary bit lines for read and search operations, and a second pair of complementary bit lines for write operations;
a first storage transistor connected between one of the first pair of complementary bit lines and the match line;
a second storage transistor connected between the other of the first pair of complementary bit lines and the match line;
a first write transistor connected between a gate of the first storage transistor and one of the second pair of complementary bit lines; and
a second write transistor connected between a gate of the second storage transistor and the other of the second pair of complementary bit lines, with both the first and second write transistors having a gate connected to the write line.

2. The dynamic CAM cell of claim 1, further comprising a diode-connected transistor connected between the match line and the first and second storage transistors.

3. The dynamic CAM cell of claim 2, further comprising first and second storage capacitors, respectively coupled to the gates of the first and second storage transistors.

4. The dynamic CAM cell of claim 3, wherein the first and second storage capacitors comprise trench capacitors having a grounded electrode.

5. The dynamic CAM cell of claim 1, wherein the first pair of complementary bit lines are interdigitated with the second pair of complementary bit lines.

6. A dynamic, content addressable memory (CAM) array, comprising:
a plurality of CAM cells arranged in rows and columns, with each row including a match line and a write line, and each column including a first pair of complementary bit lines for read and search operations, and a second pair of complementary bit lines for write operations, wherein each of the plurality of CAM cells further comprises:
a first storage transistor connected between one of the first pair of complementary bit lines and the match line;
a second storage transistor connected between the other of the first pair of complementary bit lines and the match line;
a first write transistor connected between a gate of the first storage transistor and one of the second pair of complementary bit lines; and
a second write transistor connected between a gate of the second storage transistor and the other of the second pair of complementary bit lines, with both the first and second write transistors having a gate connected to the write line.

7. The dynamic CAM array of claim 6, wherein each CAM cell further comprises a diode-connected transistor connected between the match line and the first and second storage transistors.

8. The dynamic CAM array of claim 7, wherein each CAM cell further comprises first and second storage capacitors, respectively coupled to the gates of the first and second storage transistors.

9. The dynamic CAM array of claim 8, wherein the first and second storage capacitors comprise trench capacitors having a grounded electrode.

10. The dynamic CAM array of claim 6, wherein the first pair of complementary bit lines are interdigitated with the second pair of complementary bit lines.

11. A method of operating a dynamic, content addressable memory (CAM) cell having a match line, a write line, a first pair of complementary bit lines for read and search operations, and a second pair of complementary bit lines for write operations, a first storage transistor connected between one of the first pair of complementary bit lines and the match line, a second storage transistor connected between the other of the first pair of complementary bit lines and the match line, a first write transistor connected between a gate of the first storage transistor and one of the second pair of complementary bit lines, and a second write transistor connected between a gate of the second storage transistor and the other of the second pair of complementary bit lines, with both the first and second write transistors having a gate connected to the write line, wherein the method comprises:
performing a read operation of the cell by maintaining the write line low and initially preconditioning the match line and the first pair of complementary bit lines low, selecting the cell for the read operation by bringing the match line high, and determining which of the first and storage transistors has a charge stored on its gate by detecting a charge appearing on one of the first pair of complementary bit lines, via the match line; and
performing a match operation on the cell by maintaining the write line low and initially preconditioning the match line high, driving search data onto the first pair of complementary bit lines, and determining whether the cell data matches the data presented on the first pair of complementary bit lines such that match line remains high in the event of a match and the match line discharges in the event of a mismatch.

12. The method of claim 11, wherein the CAM cell further comprises a diode-connected transistor connected between the match line and the first and second storage transistors.

13. The method of claim 12, wherein the CAM cell further comprises first and second storage capacitors, respectively coupled to the gates of the first and second storage transistors.

14. The method of claim 13, wherein the first and second storage capacitors comprise trench capacitors having a grounded electrode.

15. The method of claim 11, wherein the first pair of complementary bit lines are interdigitated with the second pair of complementary bit lines.

16. The method of claim 11, further comprising a write operation by preconditioning the match line, the first pair of complementary bit lines, and the second pair of complementary bit lines to a same potential, driving data onto the second pair of complementary bit lines, and bringing the potential on the write line to high.
